(19) United States
(12) Patent Application Publication
(10) Pub. No.: US 2025/0253172 A1
(43) Pub. Date: Aug. 7, 2025

(54) PROCESSING EQUIPMENT

(71) Applicant: PlayNitride Display Co., Ltd., MiaoLi County (TW)

(72) Inventor: Yen-Mu Chen, MiaoLi County (TW)

(73) Assignee: PlayNitride Display Co., Ltd., MiaoLi County (TW)

(21) Appl. No.: 18/628,840

(22) Filed: Apr. 8, 2024

(30) Foreign Application Priority Data
Feb. 6, 2024 (TW) 113104588

(51) Int. Cl. H01L 21/67; H01L 21/48; H01L 21/677

(52) U.S. Cl. CPC H01L 21/67138; H01L 21/485; H01L 21/67288; H01L 21/67763

(57) ABSTRACT

A processing equipment including a supply unit, a receiving unit, and a motion unit is provided. The supply unit has multiple supply sequences. Each of the supply sequences is provided with at least a first supply subset and a second supply subset. At least part of a first receiving subset is distributed in one receiving sequence. The motion unit is used to control a relative movement between the supply unit and the receiving unit, so that the first receiving subset and the second receiving subset are sequentially aligned with the first supply subset and the second supply subset of a supply sequence, and respectively define a first distribution pattern and a second distribution pattern on a supply surface of the supply unit. At least part of the first distribution pattern and at least part of the second distribution pattern are overlapped with each other in a direction.

### CROSS-REFERENCE TO RELATED APPLICATION

This application claims the priority benefit of Taiwan application serial no. 113104588, filed on Feb. 6, 2024. The entirety of the above-mentioned patent application is hereby incorporated by reference herein and made a part of this specification.

### BACKGROUND

### Technical Field

The disclosure relates to a processing technology, and more particularly, to a processing equipment.

### Description of Related Art

In a mass repair process for dies, the dies on a source substrate are transferred to a target substrate. Some positions on the source substrate will be in a crystal-deficient state after the dies are provided to the target substrate. When the amount of repair on the source substrate increases, the crystal-deficient state will begin to affect a repair yield. In other words, a die supply capacity of the source substrate gradually decreases, resulting in repair requirements for the target substrate being unable to be fully met. If the dies in a remaining complete area on the source substrate are used for repair every time, although the repair requirements for the target substrate may be met, a usage rate of the die on the source substrate will inevitably be poor.

In one alternative solution, positions of the remaining dies on the source substrate are matched with positions to be repaired on the target substrate in two-dimensional areas of specific dimensions. However, such matching process in the two-dimensional area not only takes a long time for calculation, but when the number of matchable dies is reduced to a certain ratio, it is almost impossible to continue to calculate a fully supplied matching combination. Even if the dimension of the two-dimensional area based on matching is reduced, it may only delay occurrence of the above issues to a very limited extent, and the number of repairs and time will be doubled. In addition, uniformity of an epitaxial process affects consistency of die properties on the source substrate. If the consistency of properties between the repaired die and adjacent die is also required to be considered, the difficulty of the two-dimensional matching will be even higher.

### SUMMARY

The disclosure provides a processing equipment, which may improve a usage rate of source dies and take into account repair efficiency of the dies.

A processing equipment in the disclosure includes a supply unit, a receiving unit, and a motion unit. The supply unit has multiple supply sequences arranged along a first direction. Each of the supply sequences is provided with at least a first supply subset and a second supply subset. The receiving unit has multiple receiving sequences arranged along the first direction. The receiving sequences are provided with a first receiving subset and a second receiving subset. At least part of the first receiving subset is distributed in one of the receiving sequences. At least part of the second receiving subset is distributed in another of the receiving sequences. A motion unit is used to control a relative movement between the supply unit and the receiving unit, so that the first receiving subset and the second receiving subset are sequentially aligned with the first supply subset and the second supply subset of one of the supply sequences, and respectively define a first distribution pattern and a second distribution pattern on a supply surface of the supply unit. At least part of the first distribution pattern and at least part of the second distribution pattern are overlapped with each other in a second direction perpendicular to the first direction.

Based on the above, in the processing equipment according to an embodiment of the disclosure, the distribution patterns of at least two receiving subsets of the receiving units in different receiving sequences on the supply surface of the supply unit are overlapped with each other in the direction perpendicular to the arrangement direction of the supply sequence. Accordingly, in addition to reducing the complexity of the matching algorithm, it may also maintain the distribution integrity of the remaining supply sequences on the supply unit, which helps to improve the element usage rate of the supply unit and execution efficiency of processing steps.

### BRIEF DESCRIPTION OF THE DRAWINGS

FIG. 1 is a schematic top view of a receiving unit of a processing equipment according to the first embodiment of the disclosure.

FIG. 2 is a schematic top view of a supply unit of the processing equipment according to the first embodiment of the disclosure.

FIGS. 3A to 3C are schematic flow charts of performing repairing on the receiving unit in FIG. 1 using the supply unit in FIG. 2.

FIGS. 4A to 4F are schematic cross-sectional views of a repair process of the processing equipment according to the first embodiment of the disclosure.

FIGS. 5A and 5B are schematic cross-sectional views of a repair process of a processing equipment according to another modified embodiment of the disclosure.

FIG. 6 is a schematic top view of a receiving unit of a processing equipment according to the second embodiment of the disclosure.

FIG. 7 is a schematic top view of a supply unit of the processing equipment according to the second embodiment of the disclosure.

FIGS. 8A to 8C are schematic flow charts of performing repairing on the receiving unit in FIG. 6 using the supply unit in FIG. 7.

FIG. 9 is a schematic top view of a receiving unit of a processing equipment according to the third embodiment of the disclosure.

FIG. 10 is a schematic top view of a supply unit of the processing equipment according to the third embodiment of the disclosure.

FIGS. 11A to 11D are schematic flow charts of performing repairing on the receiving unit in FIG. 9 using the supply unit in FIG. 10.

### DETAILED DESCRIPTION OF DISCLOSED EMBODIMENTS

In the accompanying drawings, the thickness of layers, films, panels, regions, and so forth are enlarged for clarity. It should be understood that when an element, such as a layer, a film, a region, or a substrate is referred to as being “on” or “connected to” another element, it can be directly on or connected to the another element, or an intermediate element may also be present. By contrast, when an element is referred to as being “directly on” or “directly connected to” another element, no intermediate element is present. As used herein, being “connected” may refer to a physical and/or electrical connection. Furthermore, being “electrically connected” may refer to the presence of other elements between the two elements.

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

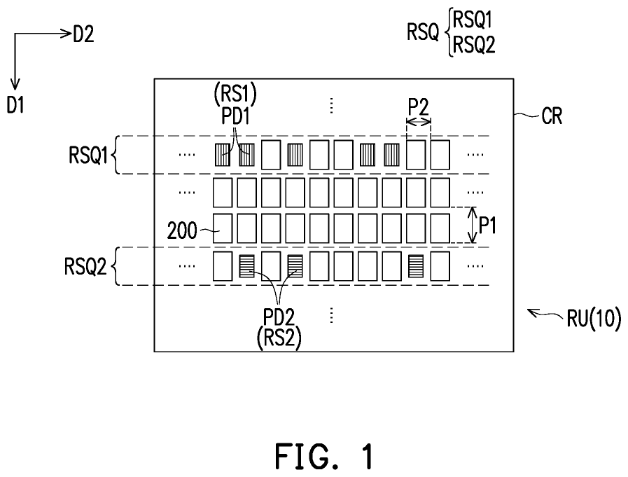

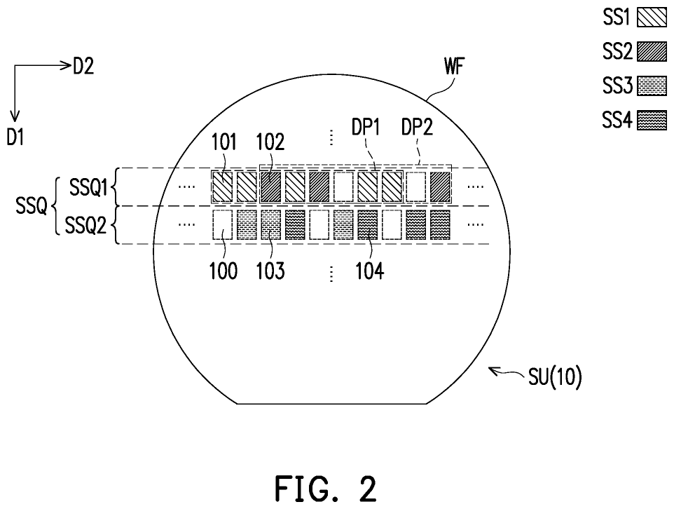

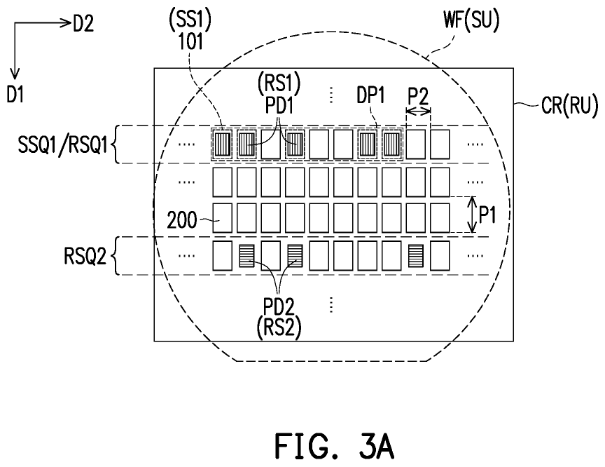

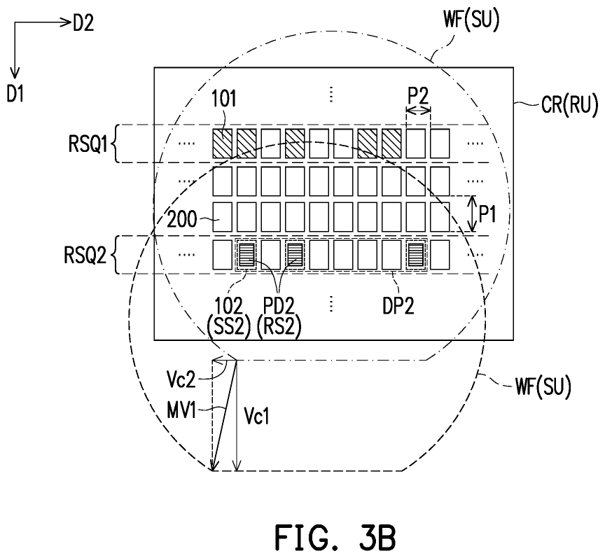

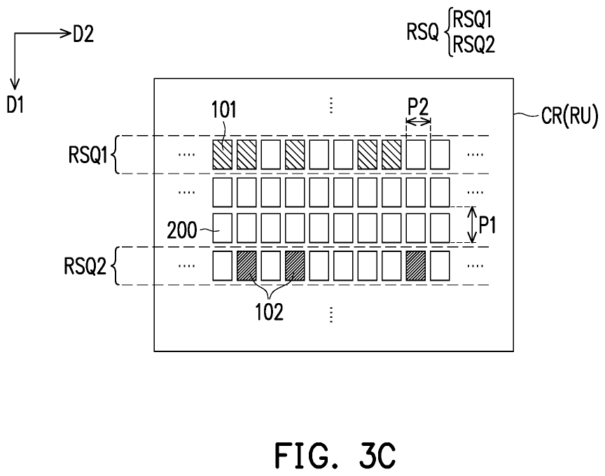

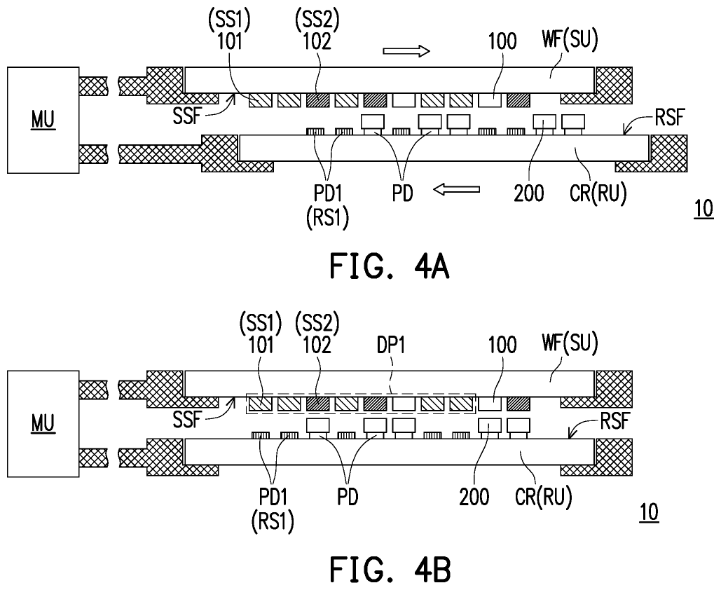

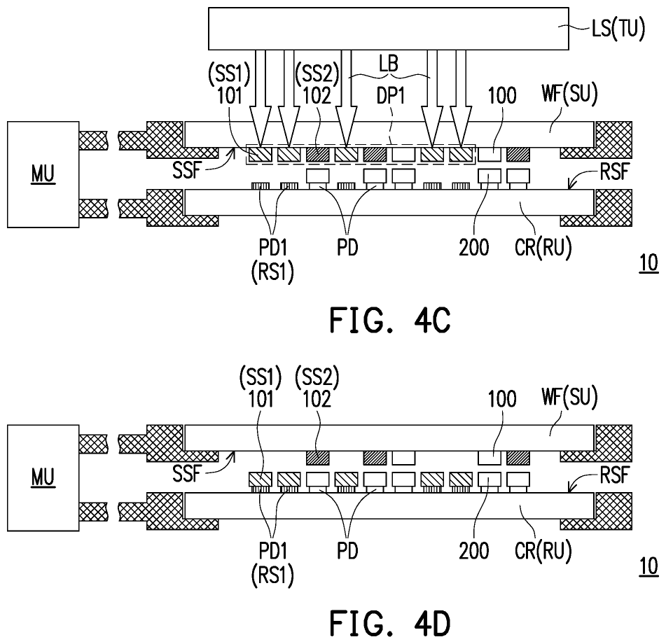

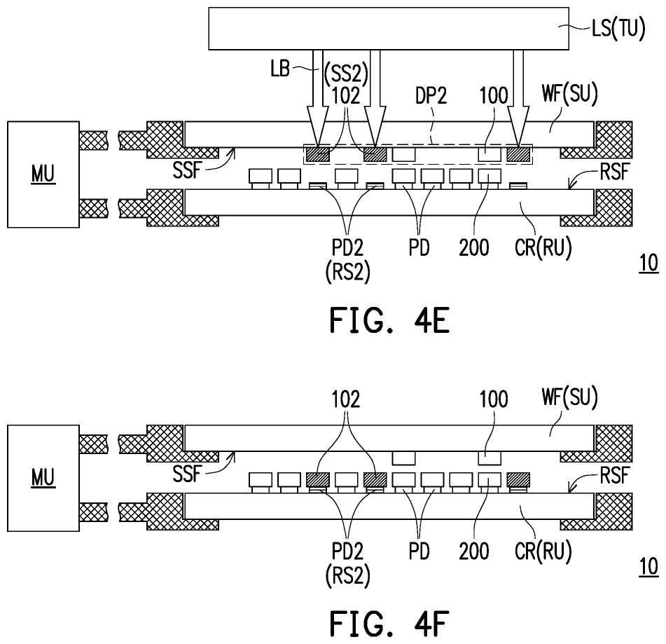

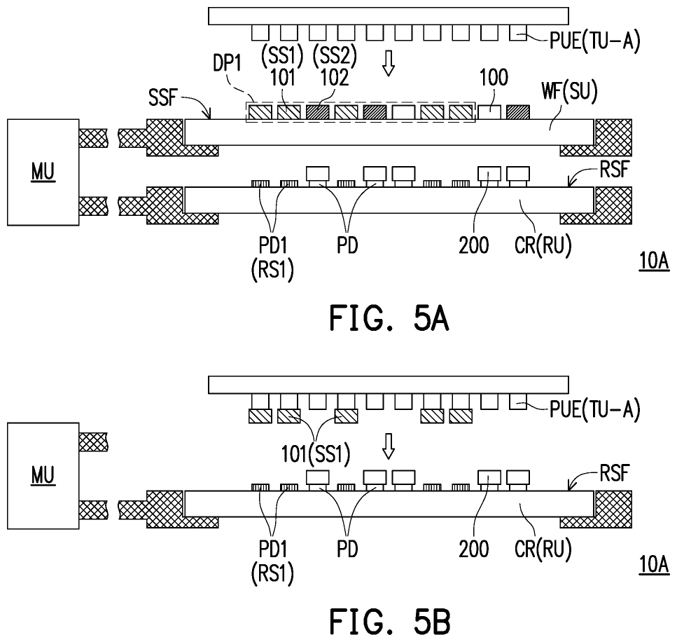

FIG. 1 is a schematic top view of a receiving unit of a processing equipment according to the first embodiment of the disclosure. FIG. 2 is a schematic top view of a supply unit of the processing equipment according to the first embodiment of the disclosure. FIGS. 3A to 3C are schematic flow charts of performing repairing on the receiving unit in FIG. 1 using the supply unit in FIG. 2. FIGS. 4A to 4F are schematic cross-sectional views of a repair process of the processing equipment according to the first embodiment of the disclosure. FIGS. 5A and 5B are schematic cross-sectional views of a repair process of a processing equipment according to another modified embodiment of the disclosure.

Referring to FIGS. 1, 2, and 4A, a processing equipment 10 includes a supply unit SU, a receiving unit RU, and a motion unit MU. The receiving unit RU has multiple receiving sequences RSQ arranged along a first direction D1, and the receiving sequences RSQ are provided with multiple receiving subsets. For example, a receiving sequence RSQ1 is provided with a receiving subset RS1, and another receiving sequence RSQ2 is provided with another receiving subset RS2.

However, the disclosure is not limited thereto. In other embodiments, the receiving subset may be divided into multiple parts and distributed in different receiving sequences. That is, correspondence between the receiving subset and the receiving sequence may not be a one-to-one relationship. For example, when the receiving subset spans an arrangement of more than two receiving sequences RSQ, during the repair process, it may be decided, according to the number and distribution of remaining elements of the supply unit SU, whether repair of the receiving subset should be completed at one time (that is, the receiving sequences RSQ are all transferred) or in multiple times (that is, only one of the receiving sequences RSQ is transferred at a time).

In this embodiment, a receiving surface RSF of the receiving unit RU may be provided with multiple pads PD arranged in an array. More specifically, the pads PD may be arranged into multiple pad rows and multiple pad columns along the first direction D1 and a second direction D2 respectively. In this embodiment, each of the receiving sequences RSQ may optionally be provided with one pad column. That is, the number of pads PD in any one of the receiving sequences RSQ and arranged along the first direction D1 is one, but the disclosure is not limited thereto.

On the other hand, the aforementioned receiving subsets may be defined by at least part of the pads PD. For example, in this embodiment, the receiving subset RS1 in the receiving sequence RSQ1 may be formed by five pads PD1, and the receiving subset RS2 in the receiving sequence RSQ2 may be formed by three pads PD2. However, the disclosure is not limited thereto.

In this embodiment, the receiving unit RU is, for example, an element carrier CR, and the receiving surface RSF are further provided with multiple elements 200. The elements 200 are, for example, multiple micro light emitting diodes, and are respectively connected to the pads PD. However, the disclosure is not limited thereto. In other embodiments, the receiving unit RU may further be a display substrate, a semiconductor wafer, or a specific carrier on the processing equipment, and the element 200 may further be a micro-transistor or other micro-elements with different functions.

In this embodiment, the elements 200 may be arranged with a pitch P1 along the first direction D1 and with a pitch P2 along the second direction D2. It is particularly important to note that some of the elements 200 will be removed due to abnormal operation or damage, and the pads (e.g., the pad PD1 and the pad PD2) of the receiving subsets may be a remaining connection material after the elements 200 are removed or a connection material that has been reset, such as a temporary adhesive or bonding metal.

On the other hand, the supply unit SU has multiple supply sequences SSQ arranged along the first direction D1. Each of the supply sequences SSQ is provided with at least two supply subsets. For example, a supply sequence SSQ1 is provided with a supply subset SS1 and a supply subset SS2, and a supply sequence SSQ2 is provided with a supply subset SS3 and a supply subset SS4. However, the disclosure is not limited thereto.

In this embodiment, a supply surface SSF of the supply unit SU may be provided with multiple elements 100 arranged in an array. More specifically, the elements 100 may be arranged into multiple element rows and multiple element columns along the first direction D1 and the second direction D2 respectively. In this embodiment, each of the supply sequences SSQ may optionally be provided with one element column. That is, the number of elements 100 in any one of the supply sequences SSQ and arranged along the first direction D1 is one, but the disclosure is not limited thereto.

The aforementioned supply subsets may be defined by at least part of the elements 100. For example, in this embodiment, the supply subset SS1 and the supply subset SS2 in the supply sequence SSQ1 may be formed by five elements 101 and three elements 102 respectively, and the supply subset SS3 and the supply subset SS4 in the supply sequence SSQ2 may be formed by three elements 103 and four elements 104 respectively. However, the disclosure is not limited thereto.

In this embodiment, the supply surface SSF of the supply unit SU is, for example, located on a semiconductor wafer WF, and the elements 100 disposed on the supply surface SSF are, for example, multiple micro light emitting diodes (micro-LED), but the disclosure is not limited thereto. In other embodiments, the supply unit may further be a chip on carrier (COC) or a specific carrier on the processing equipment, and the element 100 may further be a micro-transistor or other micro-elements with different functions.

In this embodiment, the motion unit MU is used to control a relative movement between the supply unit SU and the receiving unit RU, so that the receiving subsets on the receiving unit RU are sequentially aligned with the supply subsets on the supply unit SU, and define multiple distribution patterns on the supply surface SSF of the supply unit SU.

For example, the receiving unit RU is controlled for movement, so that the receiving subset RS1 in the receiving sequence RSQ1 and the receiving subset RS2 in the receiving sequence RSQ2 are sequentially aligned with the supply subset SS1 and the supply subset SS2 of the same supply sequence SSQ1 in the supply unit SU, and respectively define a distribution pattern DP1 (as shown in FIGS. 3A and 4B) and a distribution pattern DP2 (as shown in FIGS. 3B and 4E) on the supply surface SSF. It should be noted that when the receiving subset is aligned with the supply subset, the distribution patterns DP1 and DP2 mapped by the receiving subset on the supply surface SSF, for example, refer to a minimum and continuous distribution range that may cover all the elements in the corresponding supply subset.

It is particularly important to note that on the supply surface SSF, at least part of the distribution pattern DP1 and at least part of the distribution pattern DP2 are overlapped with each other in the second direction D2 (as shown in FIG. 2). That is, the supply subset SS1 and the supply subset SS2 have the densest arrangement in the same supply sequence SSQ1, which helps to maintain distribution integrity of the remaining elements 100 on the supply unit SU, thereby improving a subsequent matching success rate and an element usage rate of the supply unit SU.

It should be noted first that since the processing equipment 10 in this embodiment will first match the supply unit SU and the receiving unit RU before the supply unit SU repairs or processes the receiving unit RU, and first arrange the supply subsets used to repair different receiving sequences in the same supply sequence SSQ, if a configurable space is exhausted or insufficient, the supply subsets are arranged in the next supply sequence SSQ. In this way, the supply subsets may have the densest arrangement in the supply sequences SSQ.

On the other hand, from a period when the receiving subset RS1 is positioned in the supply subset SS1 to when the receiving subset RS2 is positioned in the supply subset SS1, the supply unit SU has a movement vector MV1 relative to the receiving unit RU (as shown in FIGS. 3A and 3B). That is, the supply unit SU moves relative to the receiving unit RU by three pitches P1 in the first direction D1, and moves reversely by the pitch P2 in the second direction D2.

Furthermore, the processing equipment 10 further includes a transfer unit TU (as shown in FIG. 4C), which is adapted to transfer the elements of the corresponding supply subset to the receiving unit RU according to the distribution pattern. In this embodiment, the transfer unit TU includes, for example, a laser source LS adapted to emit a laser beam LB, but the disclosure is not limited thereto. For example, after the receiving subset RS1 (i.e., the pads PD1) is aligned with the supply subset SS1 (i.e., the elements 101) (as shown in FIGS. 3A and 4B), the transfer unit TU is adapted to emit the laser beams LB toward positions of the elements 101 of the supply subset SS1 according to the distribution pattern DP1, so that the elements 101 are detached from the supply surface SSF and transferred to the pads PD1 of the corresponding receiving subset RS1 (as shown in FIGS. 4C and 4D).

After the transfer of the supply subset SS1 is completed, the receiving subset RS2 (i.e., the pads PD2) is further aligned with the supply subset SS2 (i.e., the elements 102). After the receiving subset RS2 is aligned with the supply subset SS2 (as shown in FIGS. 3B and 4E), the transfer unit TU is adapted to emit the laser beams LB toward positions of the elements 102 of the supply subset SS2 according to the distribution pattern DP2, so that the elements 102 are detached from the supply surface SSF and transferred to the pads PD2 of the corresponding receiving subset RS2 (as shown in FIGS. 3C, 4E, and 4F).

However, the disclosure is not limited thereto. In another modified embodiment, a transfer unit TU-A of a processing equipment 10A may further include multiple pickup elements PUE. The pickup elements PUE are respectively disposed corresponding to the elements 100 on the supply surface SSF. For example, during a transfer process of the elements 101 of the supply subset SS1, the transfer unit TU-A is adapted to extract the corresponding elements 101 on the supply unit SU according to the distribution pattern DP1 to be transferred to the receiving subset RS1 of the receiving unit RU (as shown in FIGS. 5A and 5B). The same method may also be applied in a transfer process of the elements 102 of the supply subset SS2. Therefore, the same details will not be repeated in the following. The repaired receiving unit RU is shown in FIG. 3C.

According to FIGS. 1, 2, and 3C, the supply subsets corresponding to at least two receiving subsets in different receiving sequences RSQ of the receiving unit RU may be distributed in the same supply sequence. For example, in this embodiment, the supply subset SS1 corresponding to the receiving subset RS1 in the receiving sequence RSQ1 and the supply subset SS2 corresponding to the receiving subset RS2 in the receiving sequence RSQ2 are distributed in the same supply sequence SSQ1. When the receiving subset RS1 and the receiving subset RS2 are sequentially aligned with the supply subset SS1 and the supply subset SS2, the distribution pattern DP1 and distribution pattern DP2 respectively defined by the receiving subset RS1 and the receiving subset RS2 on the supply surface SSF are at least partially overlapped with each other in the same supply sequence SSQ1.

In this embodiment, the supply unit SU and the receiving unit RU are matched and analyzed in a one-dimensional area. The one-dimensional area here refers to a distribution area of any one of the supply sequences SSQ on the supply unit SU or a distribution area of any one of the receiving sequences RSQ on the receiving unit RU, and in the distribution area, the numbers of elements and pads arranged along the first direction D1 are both 1. That is, taking FIGS. 1 and 2 as an example, the supply sequences SSQ1 and SSQ2 or the receiving sequences RSQ1 and RSQ2 in each matching and analysis are all elements distributed in a single column.

Compared to the current two-dimensional area matching method, computational complexity of one-dimensional area matching is lower, and it is easier to quickly obtain a completely matching combination. In addition, configuration flexibility of the supply subset on the supply unit SU may be further increased by performing matching in the one-dimensional area. For example, the supply subsets obtained by matching the receiving subsets on the receiving unit RU may first be most closely arranged along the second direction D2, that is, first arranged in the same supply sequence SSQ. If the configurable space is exhausted or insufficient, the supply subsets are arranged in the next supply sequence SSQ. Through such an arrangement, the distribution integrity of the remaining elements 100 on the supply unit SU may be maintained, thereby improving the subsequent matching success rate and the element usage rate of the supply unit SU.

Some other embodiments are provided below to describe the invention in detail, where the same reference numerals denote the same or like components, and descriptions of the same technical contents are omitted. The aforementioned embodiment may be referred for descriptions of the omitted parts, and detailed descriptions thereof are not repeated in the following embodiment.

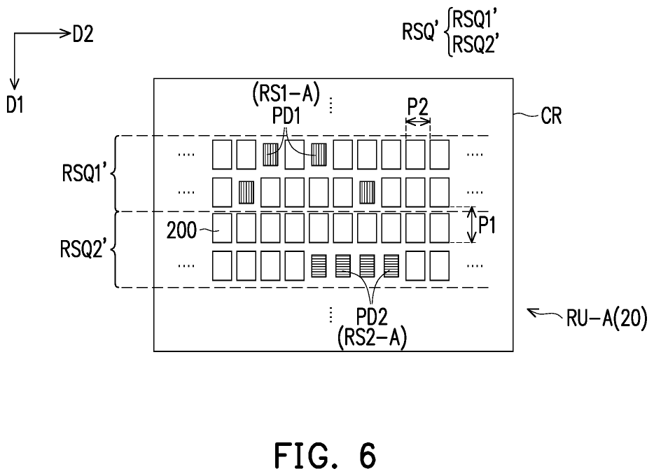

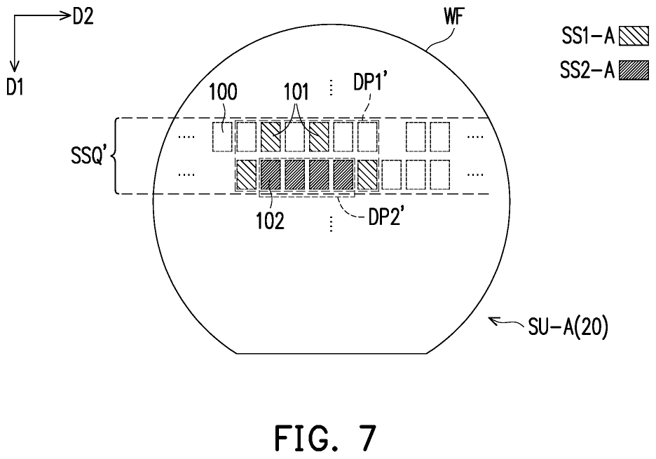

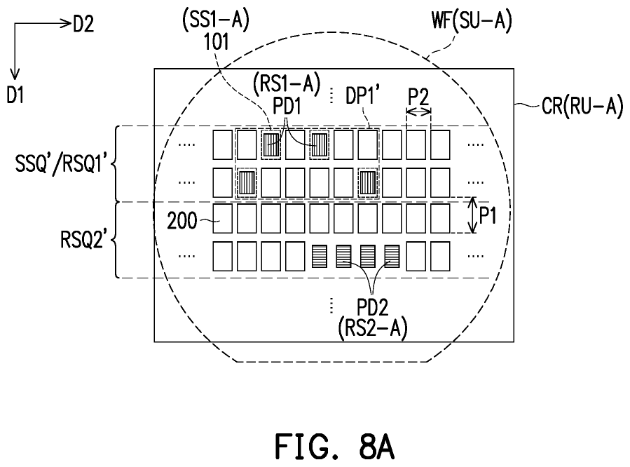

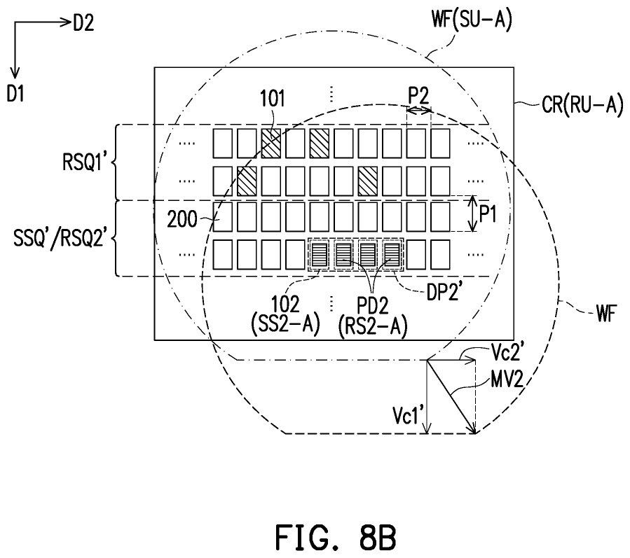

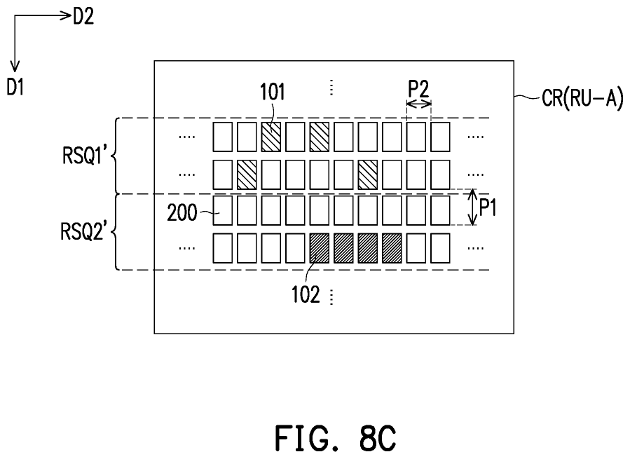

FIG. 6 s a schematic top view of a receiving unit of a processing equipment according to the second embodiment of the disclosure. FIG. 7 is a schematic top view of a supply unit of the processing equipment according to the second embodiment of the disclosure. FIGS. 8A to 8C are schematic flow charts of performing repairing on the receiving unit in FIG. 6 using the supply unit in FIG. 7.

Referring to FIGS. 6 and 7, a difference between a processing equipment 20 in this embodiment and the processing equipment 10 in FIGS. 1 and 2 is that the number of elements arranged along the first direction D1 in the supply sequence is different, and the number of pads arranged along the first direction D1 in the receiving sequence is different. For example, in this embodiment, the number of elements in each of supply sequences SSQ′ of a supply unit SU-A and arranged along the first direction D1 may be two, and the number of pads in each of a receiving sequences RSQ′ of a receiving unit RU-A and arranged along the first direction D1 may be two. That is, each of the supply sequences SSQ′ may be provided with two element columns, and each of the receiving sequences RSQ′ may be provided with two pad columns. However, the disclosure is not limited thereto. In another not-shown embodiment, the numbers of each of the supply sequences and the receiving sequences arranged along the first direction D1 may be greater than 2.

In this embodiment, the pads PD1 of a receiving subset RS1-A of the receiving unit RU-A may be dispersed in different element columns of a receiving sequence RSQ1′, and in response to the receiving subset RS1-A being set to 2 element columns, the same configuration may be optionally adopted for a receiving subset RS2-A. Taking the figure as an example, the pads PD2 are disposed in a lower pad column of a receiving sequence RSQ2′.

On the other hand, the elements 101 of a supply subset SS1-A are determined by positions of the pads PD1 of the receiving subset RS1-A, so the elements 101 are dispersed in different element columns. In particular, an upper element column in the supply sequence SSQ′ may not accommodate a position of another supply subset SS2-A due to lack of crystals or inconsistent physical properties (such as a light-emitting wavelength or brightness), so it is disposed in a lower element column. That is to say, when the number of pad columns corresponding to each of the receiving sequences RSQ′ is more than 2, and pad positions of the receiving sequences RSQ1′ and RSQ2′ may also be configured in the same group, then each of the supply sequences SSQ′ may increase arrangement flexibility of the supply subset by disposing the element columns.

Referring to FIGS. 8A and 8B, for example, during the processing or repair process, the receiving subset RS1-A and the receiving subset RS2-A will be sequentially positioned in the supply subset SS1-A and the supply subset SS2-A respectively, and respectively define a distribution pattern DP1′ (shown in FIG. 8A) and a distribution pattern DP2′ (shown in FIG. 8B) on the supply surface. From a period when the receiving subset RS1-A is positioned in the supply subset SS1-A to when the receiving subset RS2-A is positioned in the supply subset SS2-A, the supply unit SU-A has a movement vector MV2 relative to the receiving unit RU-A (as shown in the FIGS. 8A and 8B). That is, the supply unit SU-A moves relative to the receiving unit RU-A by two pitches P1 in the first direction D1, and moves by two pitches P2 in the second direction D2.

In particular, the supply unit SU-A will only move unidirectionally or not move relative to the receiving unit RU-A in a dimension of the first direction D1, and will not move in an opposite direction of the first direction D1. In other words, repair of the receiving unit RU-A will not only be performed according to an arrangement order of the receiving sequence, but also according to an arrangement order of the supply sequence. However, the supply unit SU-A may move back and forth in a dimension of the second direction D2, so that different receiving subsets in the same or different receiving sequences are sequentially aligned with the supply subsets in the same supply sequence. Accordingly, repair efficiency of the element may be greatly improved.

In this embodiment, the elements 101 of the supply subset SS1-A and the elements 102 of the supply subset SS2-A may be transferred to the pads PD1 of the receiving subset RS1-A and the pads PD2 of the receiving subset RS2-A respectively by using the transfer unit TU in FIG. 4D or the transfer unit TU-A in FIG. 5A. Therefore, relevant paragraphs of the foregoing embodiments may be referred for detailed descriptions. Therefore, the same details will not be repeated in the following. The repaired receiving unit RU-A is shown in FIG. 8C.

According to FIGS. 6, 7, and 8C, the supply subsets corresponding to at least two receiving subsets in different receiving sequences RSQ′ of the receiving unit RU-A may be distributed in the same supply sequence. For example, in this embodiment, the supply subset SS1-A corresponding to the receiving subset RS1-A in the receiving sequence RSQ1′ and the supply subset SS2-A corresponding to the receiving subset RS2-A in the receiving sequence RSQ2 are distributed in the same supply sequence SSQ′. When the receiving subset RS1-A and the receiving subset RS2-A are sequentially aligned with the supply subset SS1-A and the supply subset SS2-A, the distribution pattern DP1′ and the distribution pattern DP2′ respectively defined by the receiving subset RS1-A and the receiving subset RS2-A on the supply surface are at least partially overlapped with each other in the same supply sequence SSQ′.

In this embodiment, the distribution pattern DP2′ of the receiving subset RS2-A on the supply surface may be completely overlapped with the distribution pattern DP1′ of the receiving subset RS1-A on the supply surface. In other words, the elements 102 of the supply subset SS2-A may be disposed between the elements 101 of the supply subset SS1-A. Through the densest arrangement of the supply subsets in the supply sequence SSQ′, the distribution integrity of the remaining elements 100 on the supply unit SU-A may be effectively maintained, thereby improving a subsequent matching success rate and an element usage rate of the supply unit SU-A.

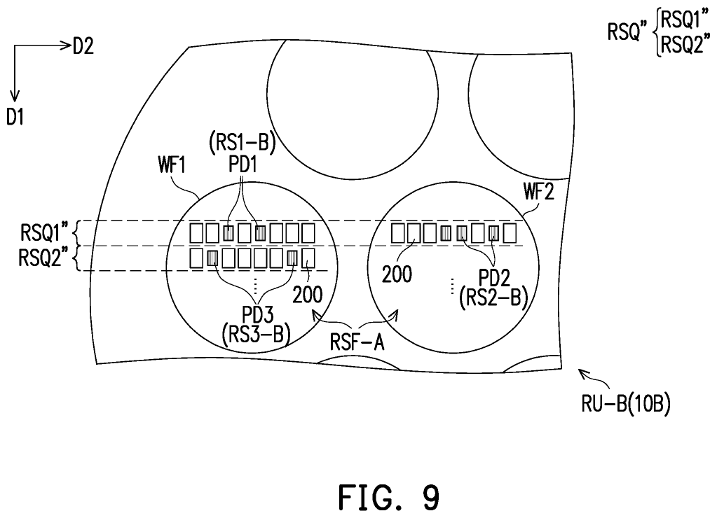

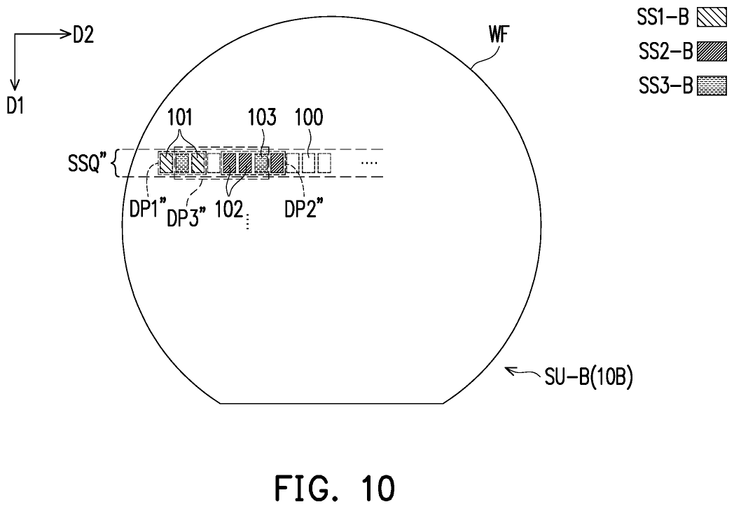

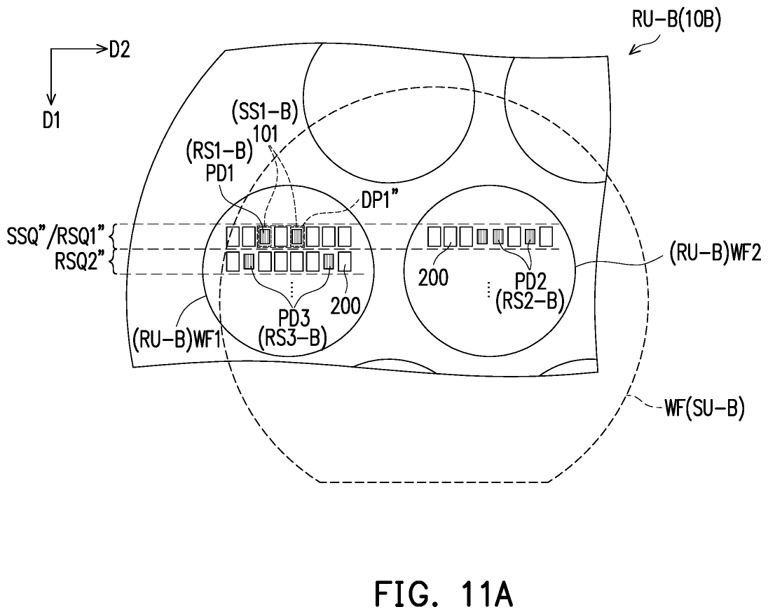

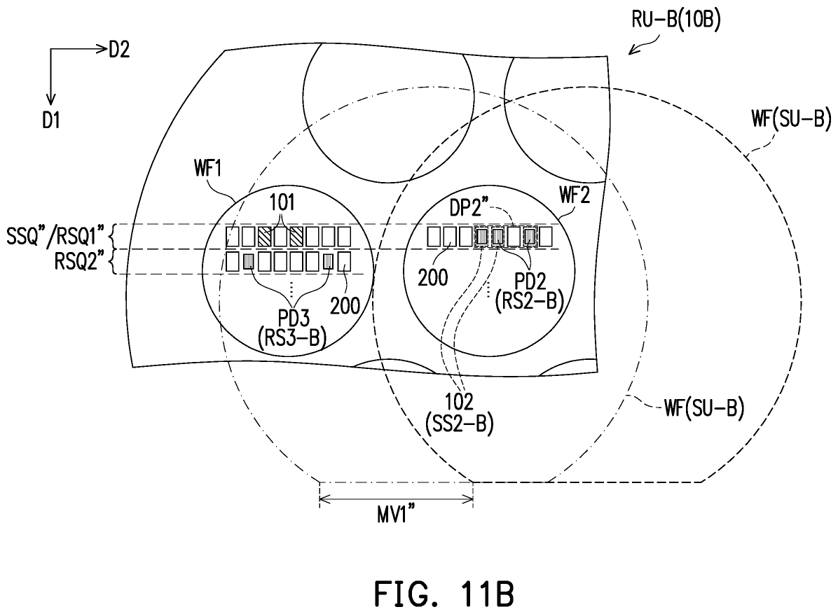

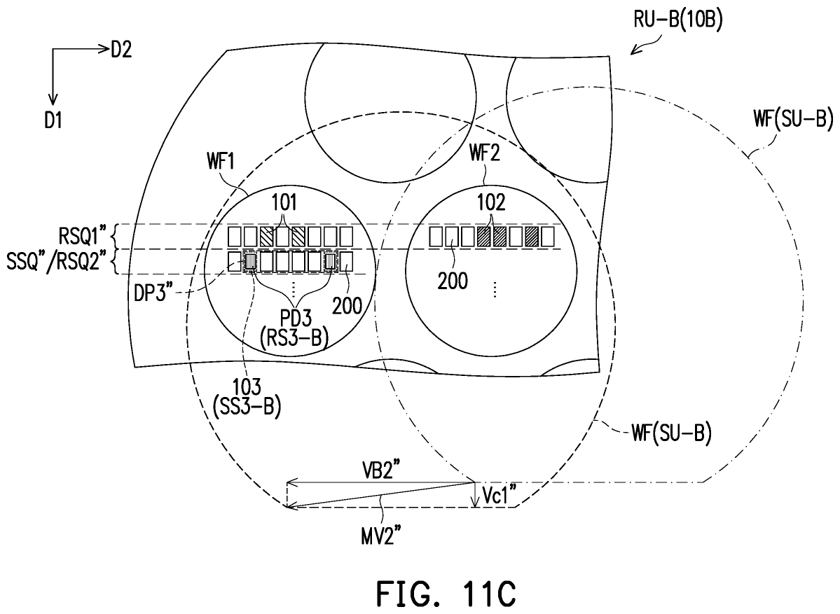

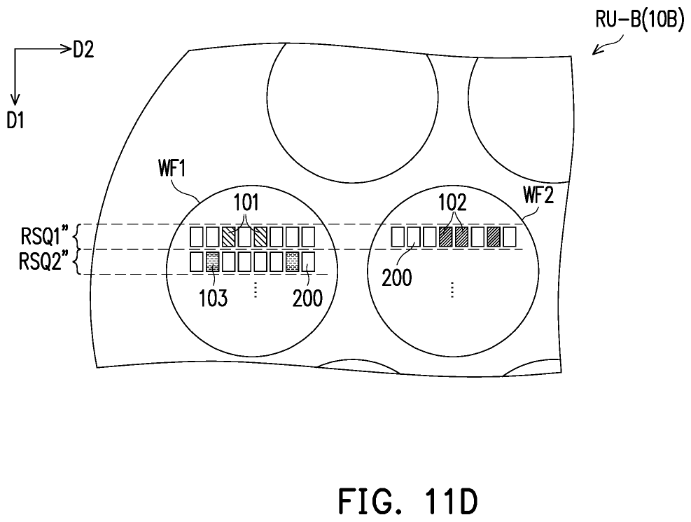

FIG. 9 is a schematic top view of a receiving unit of a processing equipment according to the third embodiment of the disclosure. FIG. 10 is a schematic top view of a supply unit of the processing equipment according to the third embodiment of the disclosure. FIGS. 11A to 11D are schematic flow charts of performing repairing on the receiving unit in FIG. 9 using the supply unit in FIG. 10.

Referring to FIGS. 9 and 10, a main difference between a processing equipment 10B in this embodiment and the processing equipment 10 in FIGS. 1 and 2 is that the implementation of the receiving unit is different. For example, in the processing equipment 10B in this embodiment, a receiving unit RU-B may be a combination of multiple semiconductor wafers (e.g., a semiconductor wafer WF1 and a semiconductor wafer WF2), and at least part of surfaces (i.e., a receiving surface RSF-A) of the semiconductor wafers is provided with multiple receiving sequences RSQ″.

In this embodiment, the semiconductor wafers are provided with the receiving subsets, and the supply subsets corresponding to the receiving subsets are all disposed on the same semiconductor wafer WF (i.e., a supply unit SU-B). For example, a receiving sequence RSQ1″ and a receiving sequence RSQ2″ on the semiconductor wafer WF1 are respectively provided with a receiving subset RS1-B and a receiving subset RS3-B, and the receiving sequence RSQ1″ on the semiconductor wafer WF2 is provided with a receiving subset RS2-B. A supply subset SS1-B, a supply subset SS2-B, and a supply subset SS3-B used to repair the receiving subsets may be disposed in a same supply sequence SSQ″ of the supply unit SU-B.

Referring to FIGS. 11A to 11C, during a processing or repair process of the receiving unit RU-B, the receiving subset RS1-B, the receiving subset RS2-B, and the receiving subset RS3-B will be sequentially and respectively positioned in the supply subset SS1-B, the supply subset SS2-B, and the supply subset SS3-B, and respectively define a distribution pattern DP1″ (shown in FIG. 11A), a distribution pattern DP2″ (shown in FIG. 11B), and a distribution pattern DP3″ (shown in FIG. 11C) on the supply surface. Furthermore, the distribution pattern DP1″, the distribution pattern DP2″, and the distribution pattern DP3″ are alternately arranged in the same supply sequence SSQ″. For example, as shown in FIG. 9, the element 101, the element 102, and the element 103 corresponding to the above distribution patterns are partially overlapped with one another in the second direction D2.

From a period when the receiving subset RS1-B is positioned in the supply subset SS1-B to when the receiving subset RS2-B is positioned in the supply subset SS2-B, the supply unit SU-B has a movement vector MV1″ relative to the receiving unit RU-B (as shown in FIGS. 11A and 11B), and the movement vector MV1″ is parallel to the second direction D2.

From a period when the receiving subset RS2-B is positioned in the supply subset SS2-B to when the receiving subset RS3-B is positioned in the supply subset SS3-B, the supply unit SU-B has movement vector MV2″ relative to the receiving unit RU-B (as shown in FIGS. 11B and 11C).

In particular, since the arrangement of the supply subsets in the supply sequence SSQ″ will consider a repairing order of the receiving sequence RSQ″ at the same time, the aforementioned densest arrangement may not only improve an element usage rate of the supply unit SU-B, but also simplify relative movement between the supply unit SU-B and the receiving unit RU-B, which helps to improve the repair efficiency of the elements. In every relative movement between the supply unit SU-B and the receiving unit RU-B, components of the movement vector of the supply unit SU-B relative to the receiving unit RU-B in the first direction D1 are greater than 0 (e.g., the movement vector MV2″) or equal to 0 (e.g., the movement vector MV1″), and will not move in the opposite direction of the first direction D1. That is to say, in a process of the supply unit SU-B sequentially positioning the receiving subset RS1-B, the receiving subset RS2-B, and the receiving subset RS3-B, the supply unit SU-B will only move unidirectionally in the first direction D1 without turning back. Therefore, repair of the receiving unit RU-B will not only be performed according to the arrangement order of the receiving sequence, but also according to the arrangement order of the supply sequence. However, the supply unit SU-B may move back and forth in the dimension of the second direction D2, so that different receiving subsets on the same or different semiconductor wafers are sequentially aligned with the supply subsets in the same supply sequence. Accordingly, the repair efficiency of the element may be greatly improved.

The repaired receiving unit RU-B is shown in FIG. 11D.

Based on the above, in the processing equipment according to an embodiment of the disclosure, the distribution patterns of at least two receiving subsets of the receiving units in different receiving sequences on the supply surface of the supply unit are overlapped with each other in the direction perpendicular to the arrangement direction of the supply sequence. Accordingly, in addition to reducing the complexity of the matching algorithm, it may also maintain the distribution integrity of the remaining supply sequences on the supply unit, which helps to improve the element usage rate of the supply unit and execution efficiency of processing steps.

What is claimed is:

1. A processing equipment, comprising:
a supply unit having a plurality of supply sequences arranged along a first direction, wherein each of the supply sequences is provided with at least a first supply subset and a second supply subset;
a receiving unit having a plurality of receiving sequences arranged along the first direction, wherein the receiving sequences are provided with a first receiving subset and a second receiving subset, at least part of the first receiving subset is distributed in one of the receiving sequences, and at least part of the second receiving subset is distributed in another of the receiving sequences; and
a motion unit used to control a relative movement between the supply unit and the receiving unit such that the first receiving subset and the second receiving subset are sequentially aligned with the first supply subset and the second supply subset of one of the supply sequences, and respectively define a first distribution pattern and a second distribution pattern on a supply surface of the supply unit,
wherein at least part of the first distribution pattern and at least part of the second distribution pattern are overlapped with each other in a second direction perpendicular to the first direction.

2. The processing equipment according to claim 1, wherein the supply surface of the supply unit is provided with a plurality of elements, at least part of the elements defines the first supply subset and the second supply subset, and the processing equipment further comprises:
a transfer unit adapted to transfer part of the elements defining the first supply subset and the second supply subset to the receiving unit according to the first distribution pattern and the second distribution pattern.

3. The processing equipment according to claim 2, wherein the elements are a plurality of micro light emitting diodes.

4. The processing equipment according to claim 2, wherein the transfer unit comprises a laser source or a plurality of pickup elements.

5. The processing equipment according to claim 2, wherein the supply unit comprises a semiconductor wafer or an element carrier.

6. The processing equipment according to claim 1, wherein from a period when the first receiving subset is positioned in the first supply subset to when the second receiving subset is positioned in the second supply subset, the supply unit and the receiving unit have the relative movement in the first direction and/or the second direction.

7. The processing equipment according to claim 1, wherein the supply surface of the supply unit is provided with a plurality of elements, at least part of the elements defines the first supply subset and the second supply subset, and a number of the elements in any one of the supply sequences and arranged along the first direction is greater than or equal to 2.

8. The processing equipment according to claim 1, wherein the supply surface of the supply unit is provided with a plurality of elements, at least part of the elements defines the first supply subset and the second supply subset, and a number of the elements in any one of the supply sequences and arranged along the first direction is 1.

9. The processing equipment according to claim 1, wherein the receiving unit comprises at least one semiconductor wafer or at least one element carrier, and at least part of a surface of the at least one semiconductor wafer or the at least one element carrier is provided with the receiving sequences of the receiving unit.

10. The processing equipment according to claim 9, wherein the at least one semiconductor wafer or the at least one element carrier is a plurality of semiconductor wafers or a plurality of element carriers, and the first receiving subset and the second receiving subset are respectively disposed on two of the semiconductor wafers or the element carriers.

11. The processing equipment according to claim 1, wherein each of the supply sequences is further provided with a third supply subset, the receiving sequences are further provided with a third receiving subset, and after the first receiving subset and the second receiving subset are sequentially aligned with the first supply subset and the second supply subset of the one of the supply sequences, the motion unit further controls the relative movement between the supply unit and the receiving unit, so that the third receiving subset is aligned with the third supply subset,
from a period when the first receiving subset is positioned in the first supply subset to when the second receiving subset is positioned in the second supply subset, the supply unit has a first movement vector relative to the receiving unit,
from a period from when the second receiving subset is positioned at the second supply subset to when the third receiving subset is positioned at the third supply subset, the supply unit has a second movement vector relative to the receiving unit, and components of the first movement vector and the second movement vector respectively in the first direction is greater than or equal to 0.
